(19) United States
(12) Patent Application Publication
(10) Pub. No.: US 2012/0293111 A1
(43) Pub. Date: Nov. 22, 2012

(54) MOBILE SOLAR POWER-GENERATING SYSTEM

(75) Inventors: Sergio Sentinelli, Palestrina (RM) (IT); Marco D'Uffizi, Palestrina (RM) (IT); Andrea Sbardella, Palestrina (RM) (IT)

(73) Assignee: PRO D3 S.R.L., Leini (TO) (IT)

(21) Appl. No.: 13/574,826

(22) PCT Filed: Feb. 3, 2011
(86) PCT No.: PCT/IT11/00028

§ 371 Date: Jul. 24, 2012

(30) Foreign Application Priority Data
Feb. 4, 2010 (IT) RM2010U000015

(51) Int. Cl. H01L 31/042; H02J 7/00

(52) U.S. Cl. 320/101

(57) ABSTRACT

A mobile solar power-generating system includes a prismatic container (1) having a top wall (10), a bottom wall (11) and side walls. A central photovoltaic panel (6) is supported in a tiltable manner on the top wall (10) by supporting elements, on each of the sides of the central photovoltaic panel (6) being hinged a correspondent transversal photovoltaic panel (61, 62, 63, 64) hanging downward in a rest position and being able to rotate 90 degrees upward. On a side of each transversal photovoltaic panel is hinged a side photovoltaic panel (610, 620, 630, 640) that is designed to fold down with respect to the relevant transversal photovoltaic panel (61, 62, 63, 64). Mutual engagement elements are provided for keeping coplanar the transversal photovoltaic panels and the side photovoltaic panels to the central photovoltaic panel (6) when the power-generating system is in an operating position.

### TECHNICAL FIELD

The present invention relates to a mobile solar power-generating system.

### BACKGROUND ART

Power-generating system of this kind are already known. See, for example, the patent application RM2006A000294 relating to a helitransportable self-powered unit comprising a container and a telescoping mast able to support solar panels, and also means designed to extend a telescoping mast after its manual installation on the vertical rear wall of the container. The solar panels have to be removed from the container and positioned on the telescoping mast through solar panel holder arms that are supported by the telescoping mast. Even if this deployment can be done by one person, however it is not easy and uncomfortable and implies waste of time.

In this context, the technical task of the present invention is to provide a mobile solar power-generating system that overcomes the above mentioned drawbacks of the prior art.

### DISCLOSURE OF INVENTION

In particular, an object of the present invention is to provide a mobile solar power-generating system able to allow photovoltaic panels to be deployed in a comfortable and easy way.

A further object of the present invention is to provide a mobile solar power-generating system that permits a quick deployment of the photovoltaic panels from a compact arrangement to an extended arrangement as well as a quick deployment in reverse order.

The stated technical task and the specified objects are generally achieved by a mobile solar power-generating system comprising the technical features set forth in one or more enclosed claims.

### BRIEF DESCRIPTION OF DRAWINGS

Further features and advantages of the present invention will be mostly clear by an indicative and therefore not limiting description of a preferred example of a mobile solar power-generating system as illustrated in the accompanying drawings in which:

FIG. 1 is a front view of the power-generating system according to the invention;

FIG. 2 is a cross-section view along the lines A-A in FIG. 1;

FIG. 3 is a cross-section view along the lines B-B in FIG. 1;

FIG. 4 is a top view, partially cut away, of the power-generating system according to the invention;

FIG. 5 is a cross-section view along the lines C-C in FIG. 4;

FIGS. 6 to 12 are isometric views showing subsequent arrangements in deploying the photovoltaic panels of the power-generating system according to the invention;

FIGS. 13 to 15 are a side view, a front view and a rear view respectively of the power-generating system in FIG. 12;

FIG. 16 is a fragmentary plan view of photovoltaic panels of the power-generating system in an operation position; and

FIG. 17 is a diagrammatic view of a circuit layout of components of the power-generating system according to the invention.

### BEST MODE FOR CARRYING OUT THE INVENTION

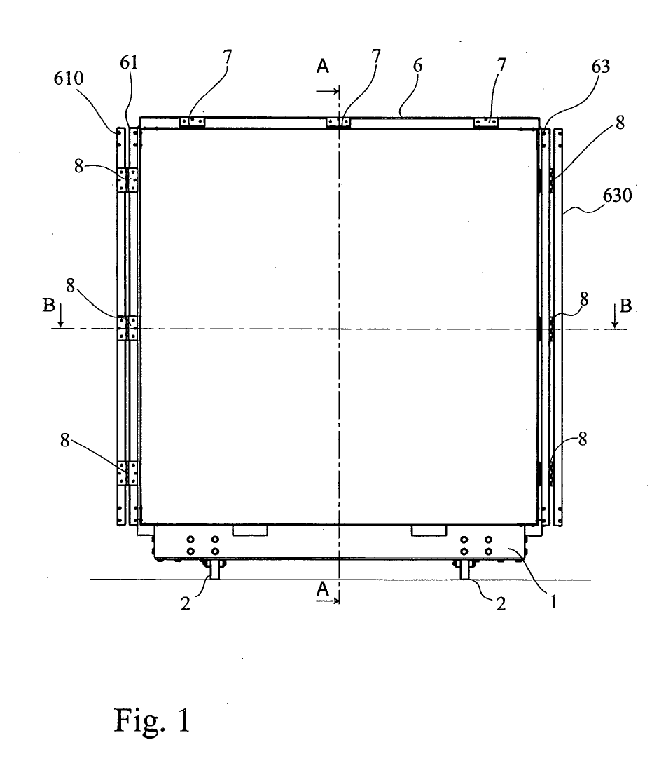

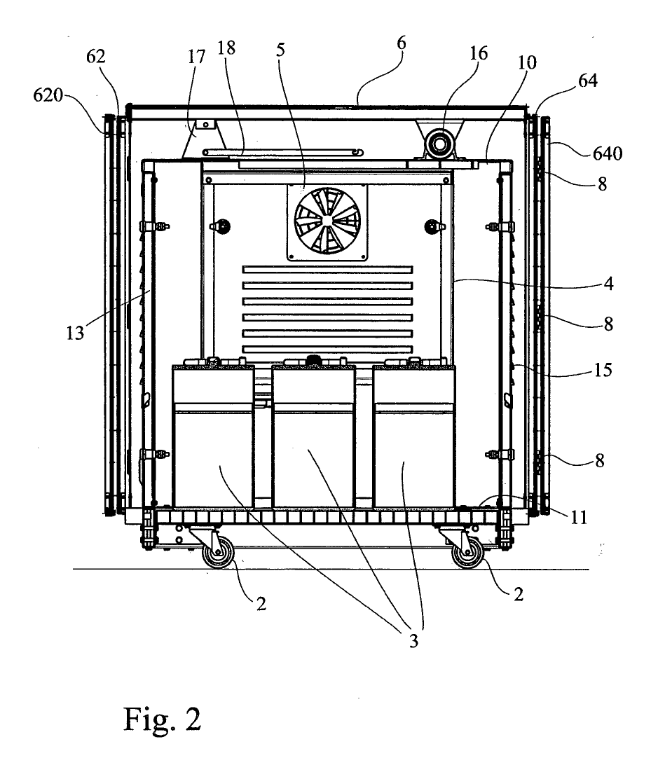

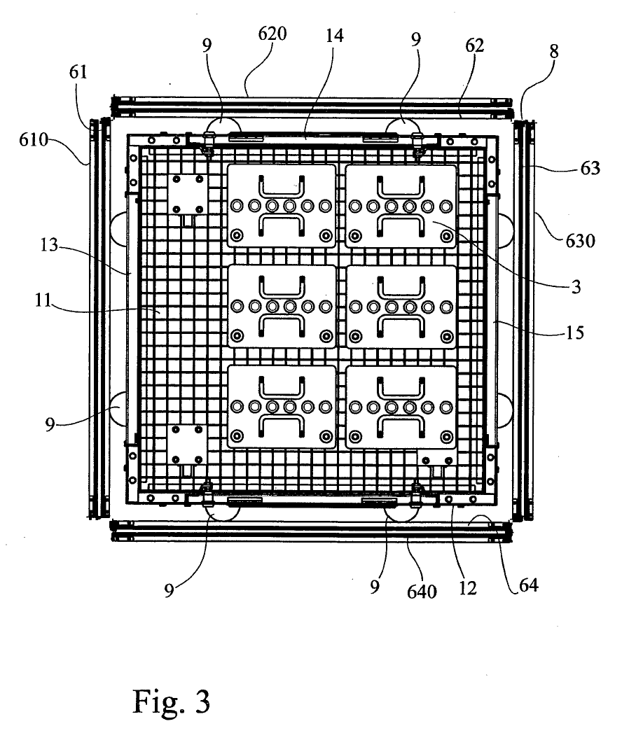

First, reference is made to FIGS. 1 to 5 in which the power-generating system according to the invention is shown in various views and cross-section views. In particular, in FIG. 1, which is a front view, indicated as 1 is a container that is provided with wheels generally indicated as 2. The container 1, which is shown in more detail in the cross-section views of FIGS. 2 and 3 made along the lines A-A and B-B in FIG. 1 respectively, is prismatic and has a top wall 10, a bottom wall 11 and side walls 12, 13, 14, and 15. Shown inside the container 1 is a plurality of accumulator batteries indicated generally as 3 and an housing 4 for the circuit of the power-generating system. The housing 4 is provided with a fan 5. A central photovoltaic panel 6 is supported in a tiltable manner on the top wall 10 by supporting means described below. Hinged on each of the sides of the central photovoltaic 6 by cylindrical hinges 7 is a correspondent transversal photovoltaic panel 61, 62, 63, 64, hanging downward in a rest position. Each transversal photovoltaic panel 61, 62, 63, 64, is able to rotate 90 degrees upward so that it is arranged coplanar to the central photovoltaic panel 6. Hinged on a side of each transversal photovoltaic panel 61, 62, 63, 64, consecutive to the hinging side by the cylindrical hinges 7 with the central photovoltaic panel 6 is a side photovoltaic panel 610, 620, 630, 640, by cylindrical hinges 8. Each side photovoltaic panel 610, 620, 630, 640, is designed to fold down with respect to the relevant transversal photovoltaic panel 61, 62, 63, 64 in a manner that each side photovoltaic panel 610, 620, 630, 640, can be arranged in both a overlapped position to the relevant transversal photovoltaic panel 61, 62, 63, 64, and a 180 degrees rotated position.

Situated on the side walls 12, 13, 14, 15 is a multiplicity of abutment elastic members 9 for transversal photovoltaic panels 61, 62, 63, 64. The transversal photovoltaic panels 61, 62, 63, 64, rest against the abutment elastic members 9 when they are in their rest position.

The supporting means of the central photovoltaic panel 6 comprises a pivot point coupling 16 made of at least a couple of bearings and at least a support member 17 for horizontally supporting the central photovoltaic panel 6.

At least a rod 18 acts as a strut for keeping the central photovoltaic panel 6 sloping from the top wall 10 of the container 1.

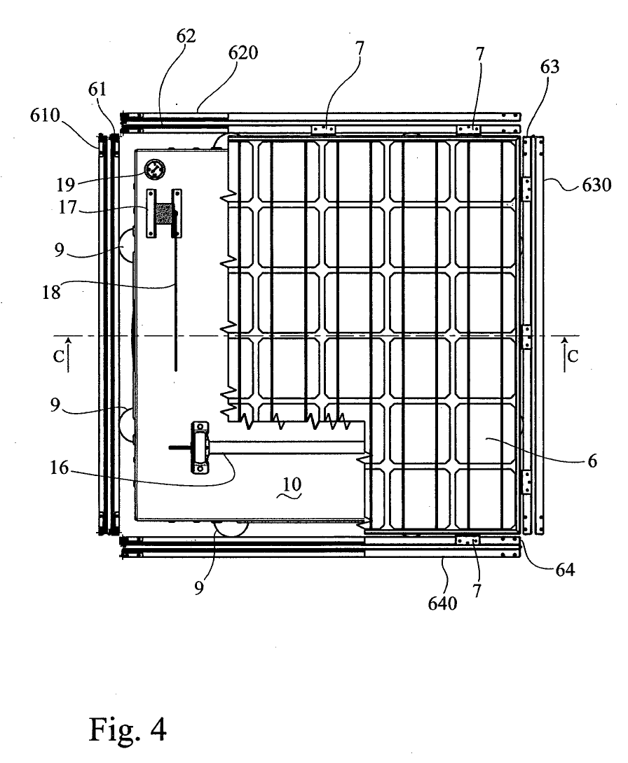

With reference to FIG. 4, which is a top view, partially cut away, of the power-generating system according to the invention, in addition to the pivot point coupling 16, the support member 17 and the rod 18, there is shown a compass 19 that is positioned on the top wall 10 and is suitable for orienting the power-generating system bearing the photovoltaic panels.

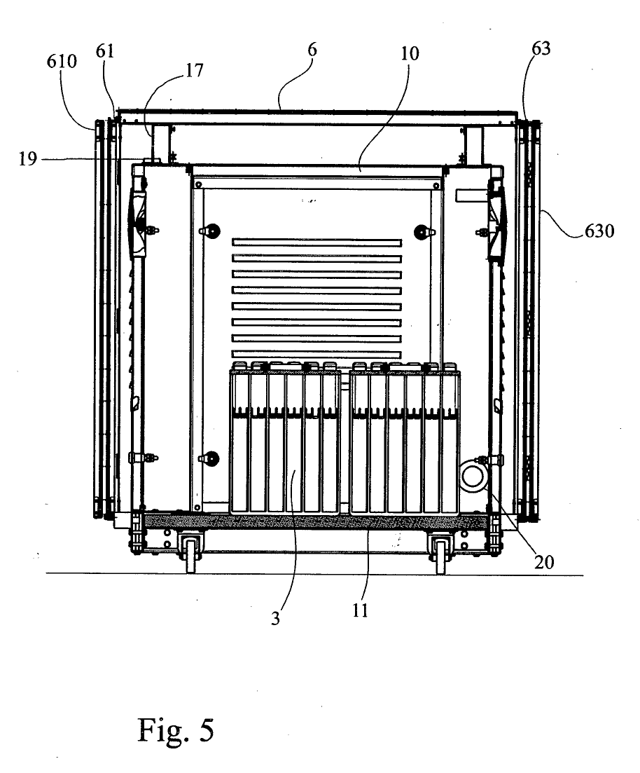

In FIG. 5, which is a cross-section view along the lines C-C in FIG. 4, indicated as 20 is a socket of the circuit of the power-generating system described below.

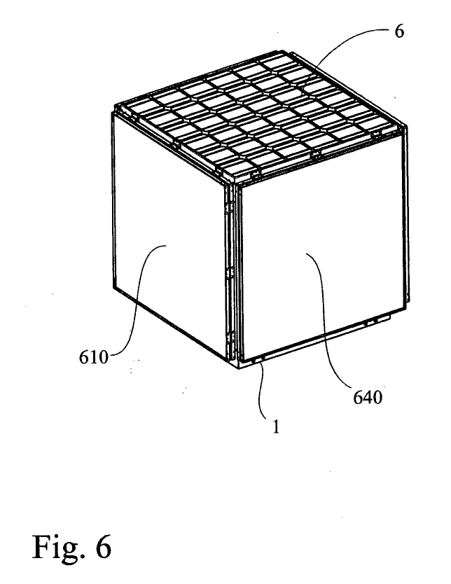

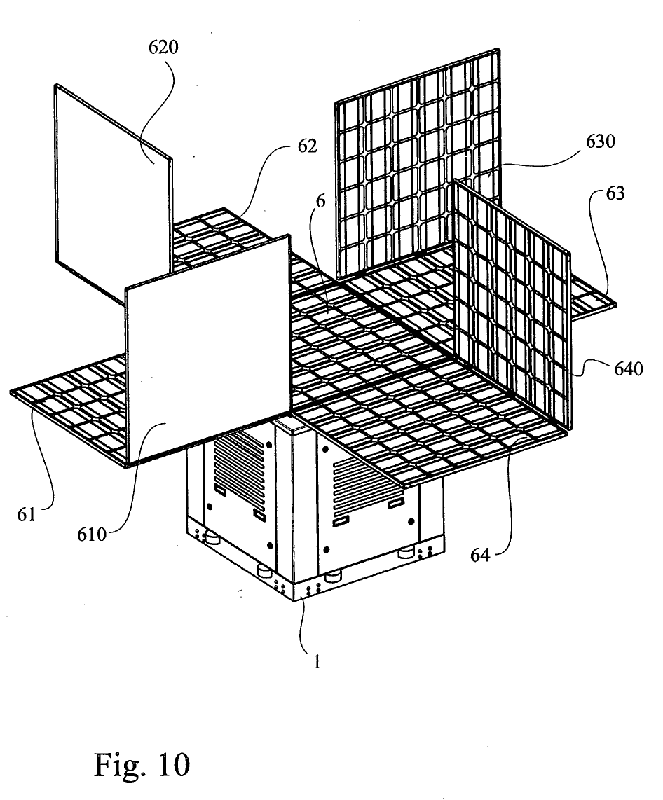

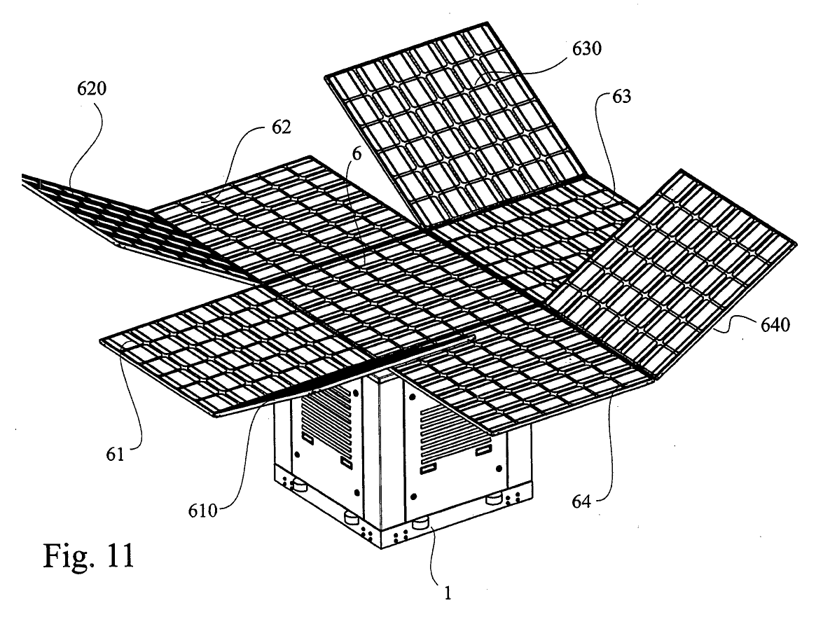

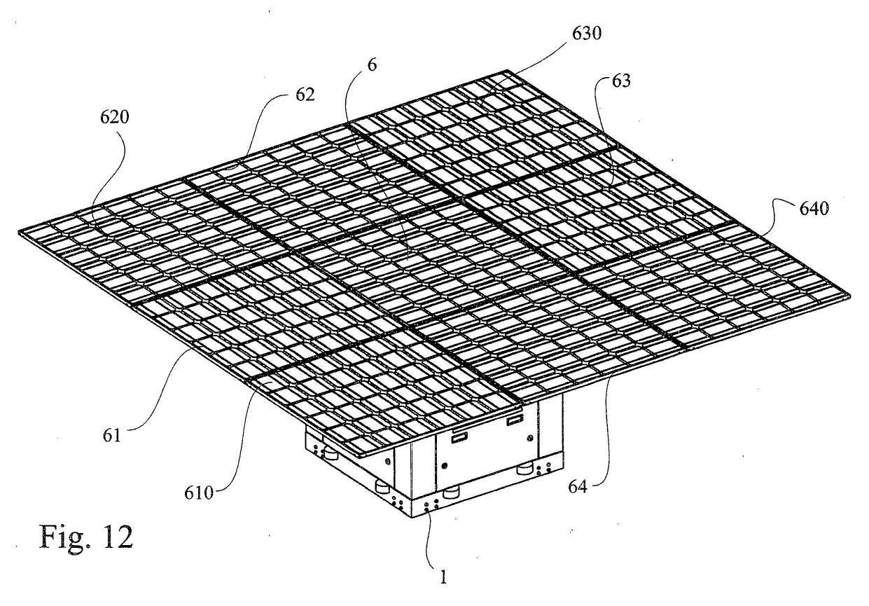

With reference to FIGS. 6 to 12, there are shown in an isometric view subsequent steps to transform the power-generating system from the rest position shown in FIG. 6, which is the same as in FIG. 1, i.e. having transversal and side photovoltaic panels in vertical position, to the operating position shown in FIG. 12.

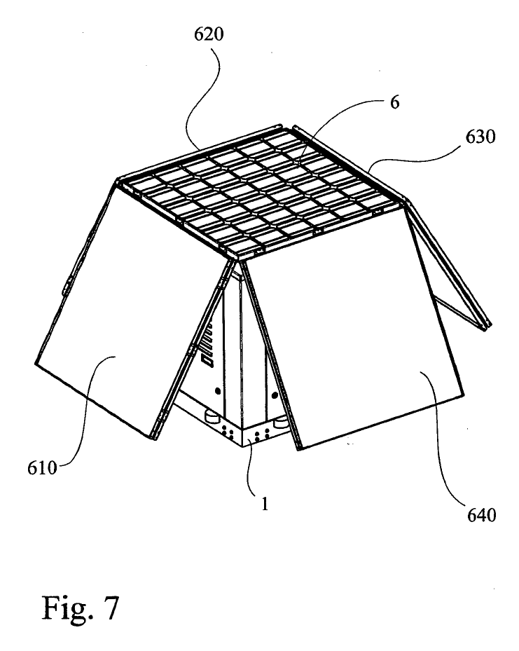

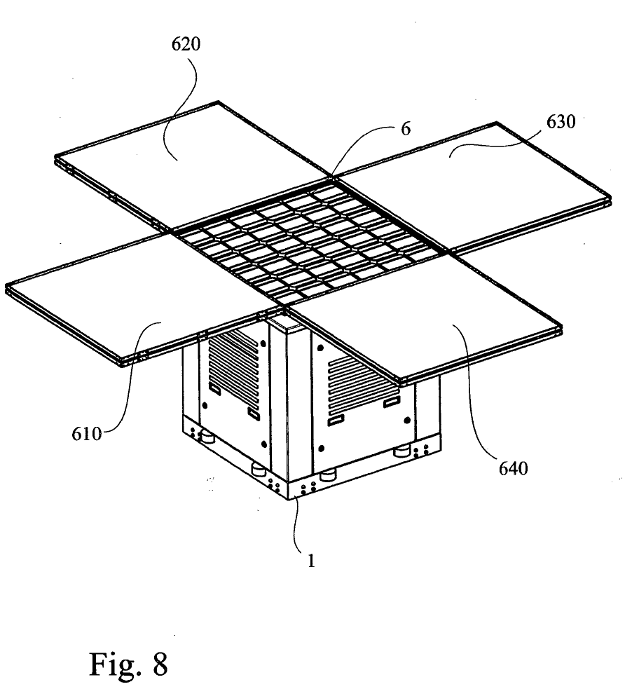

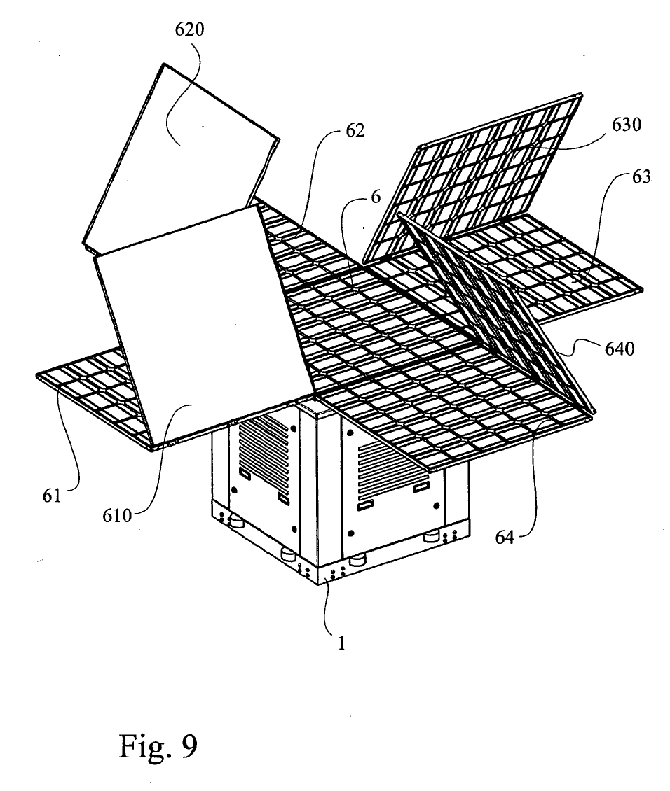

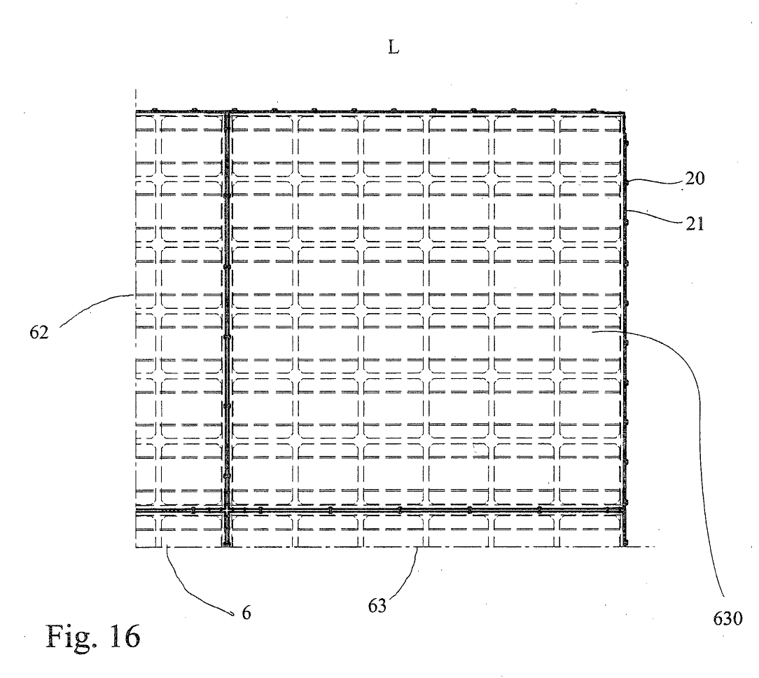

In FIG. 7 these panels are shown in an upward slightly rotated position, and in FIG. 8 in a horizontal position, in which the transversal panels 61, 62, 63, 64 are coplanar to the central panel 6, and the side photovoltaic panels 610, 620, 630, 640 are overlapped to them. From this position the side panels 610, 620, 630, 640 are gradually rotated 180 degrees (FIGS. 9, 10, 11, 12) so that they themselves become coplanar to the central panel 6. In order to keep them coplanar, mutual engagement means are provided in the form of bars 21 and bolts 22 that connect mutually the transversal and side photovoltaic panels as shown in FIG. 16, which is a fragmentary enlarged view of the photovoltaic panels 6, 62, 640, and 64.

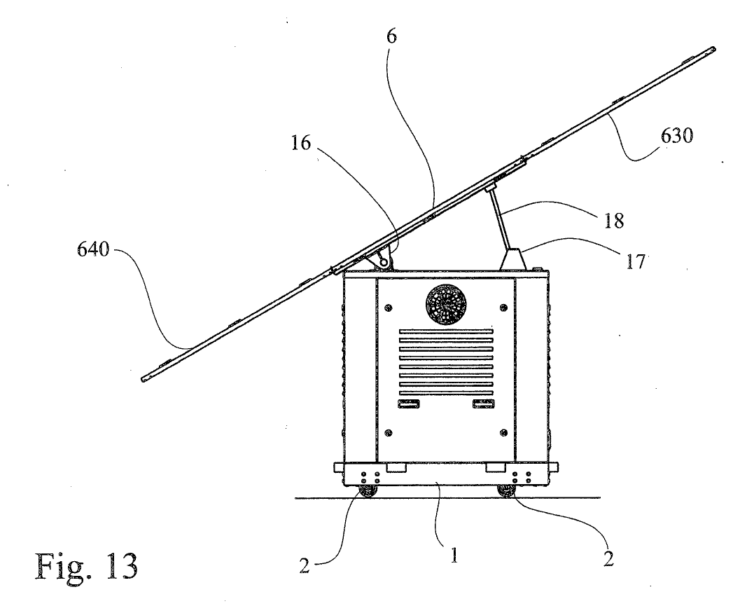

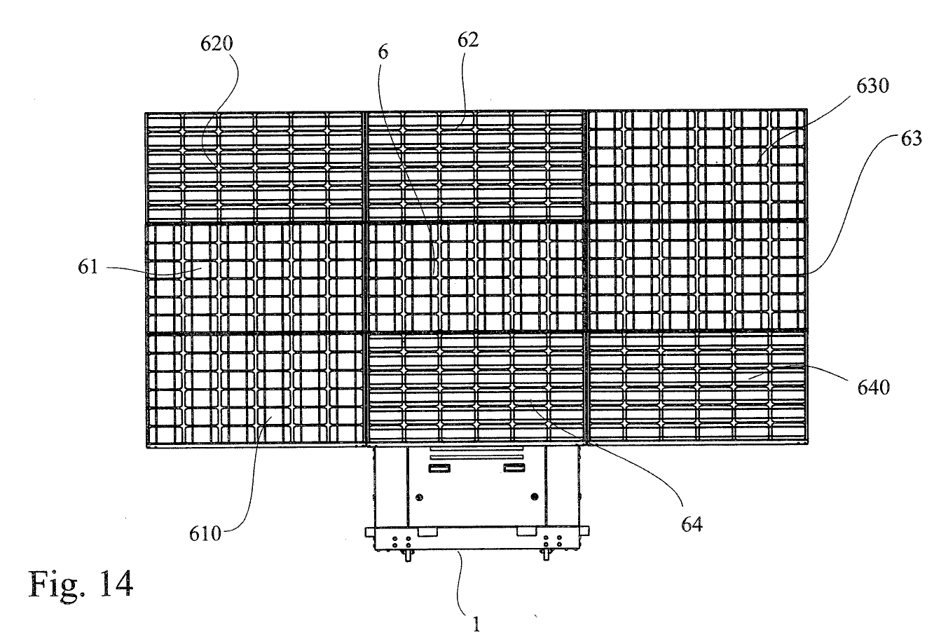

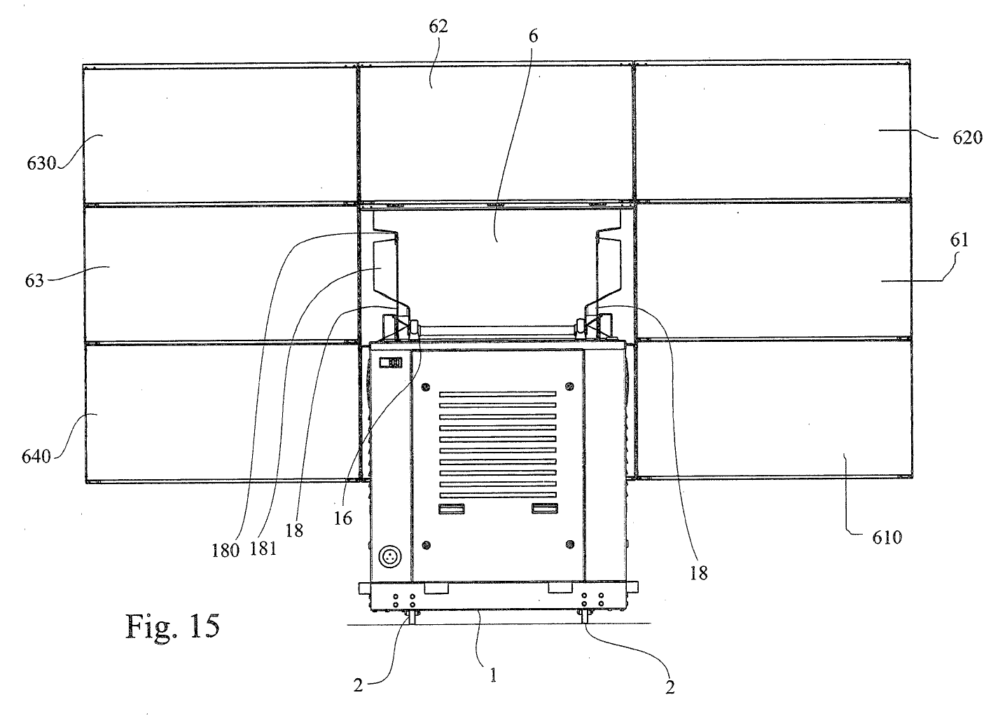

Once the central, transversal and side photovoltaic panels form one assembly, this assembly can be sloped with respect to the horizontal plan as shown in FIGS. 13, 14, and 15, which are a side view, a front view and a rear view respectively, of the power-generating system in FIG. 12. Even if it is not specifically indicated, the slope of the photovoltaic panels as a whole is adjustable by either positioning the rod 18 with respect to the top wall 10 of the container 1, or varying the length of the rod 18 itself. In the example shown in FIG. 15, two rods 18 are provided to be inserted in recesses 180 made in a shaped abutment plate 181.

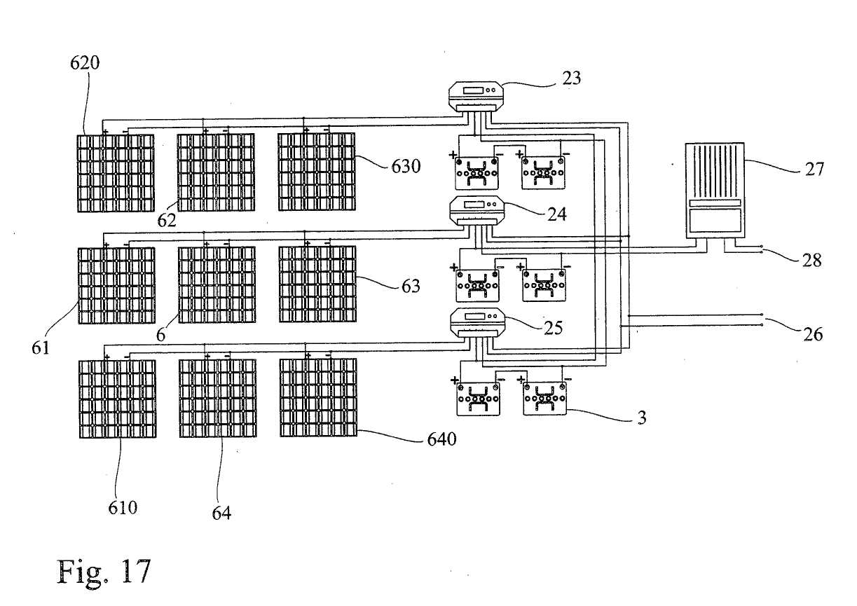

In FIG. 17 a diagrammatic view of a circuit layout of components of the power-generating system according to the invention is shown.

The panels 620-62-630, 61-6-63, 610-40-640, for example the Solon Black 130/04 module 135 Wp manufactured by Solon S.p.A. (Italy), are connected to respective charge regulators 23, 24, 25 for charging relevant batteries 3, for example Opz Solar 140 manufactured by SumSol (Spain), being coupled in series. A 24 V or 12 V output 26 exits from the charge regulators 23, 24, 25 and an inverter 27 is connected to both the charge regulators 23, 24, 25 and the couples of batteries 3 for transforming direct current into alternate current, with a 220 V alternate current output 28.

Even if not shown, the power-generating system according to the invention is provided with an electronic meter adapted to indicate the remaining time until the stored energy is wasted.

Advantageously the photovoltaic panels are of a quadrilateral shape with right angles in a manner that they can match the side walls of the prismatic container 1. Further, it is suitable that the sides of the quadrilateral shape are equal, i.e. all are of the same length L, as shown in FIG. 16.

In the operating position of the power-generating system the bars 21 and the bolts 22 mutually connect the transversal and side photovoltaic panels around the central one. As the panels are nine, the total surface of the whole square having a side length of 3 L is 3 L×3 L.

It is clear that dimensions can be chosen optionally by considering the power production needs. Further the wheels, that are shown as rollers 2, can be sized differently so that the power-generating system can be moved also on a soil that is not smooth and compact.

1-9. (canceled)

10. A mobile solar power-generating system comprising a prismatic container (1) internally housing at least a charge regulator (23) and at least an accumulator battery (3) and externally sustaining at least a central photovoltaic panel (6), the container (1) having a top wall (10), a bottom wall (11) and side walls (12, 13, 14, 15), and the central photovoltaic panel (6) being supported in a tiltable manner on the top wall (10) by supporting means, on each of the sides of the central photovoltaic (6) being hinged by hinges (7) a correspondent transversal photovoltaic panel (61, 62, 63, 64) hanging downward in a rest position and being able to rotate 90 degrees upward so that it is arranged coplanar to the central photovoltaic panel (6); characterised in that hinged by means of hinges (8) on a side of each transversal photovoltaic panel (61, 62, 63, 64), consecutive to the hinging side with the central photovoltaic panel (6), is a side photovoltaic panel (610, 620, 630, 640) that is designed to fold down with respect to the relevant transversal photovoltaic panel (61, 62, 63, 64); mutual engagement means being provided for keeping coplanar the transversal photovoltaic panels (61, 62, 63, 64) and the side photovoltaic panels (610, 620, 630, 640), to the central photovoltaic panel (6) when the power-generating system is in an operating position.

11. The power-generating system according to claim 10, wherein said supporting means comprises at least a pivot point coupling (16), at least a support member (17) for horizontally supporting the central photovoltaic panel (6) and at least a rod (18) acting as a strut for keeping the central photovoltaic panel (6) sloping from the top wall (10) of the container (1).

12. The power-generating system according to claim 11, wherein the bottom wall (11) is provided with wheels (2).

13. The power-generating system according to claim 12, wherein the photovoltaic panels (6, 61, 62, 63, 64, 610, 620, 630, 640) are of a quadrilateral shape with right angles.

14. The power-generating system according to claim 13, wherein the sides of the quadrilateral shape are equal.

15. The power-generating system according to claim 10, wherein the side walls of the container (1) have abutment elastic members (9) for transversal photovoltaic panels (61, 62, 63, 64), against which the transversal photovoltaic panels (61, 62, 63, 64) rest when they are in their rest position.

16. The power-generating system according to claim 10, characterised in that said mutual engagement means comprises bars (21) and bolts (22) that mutually connect the transversal photovoltaic panels (61, 62, 63, 64) and side photovoltaic panels (610, 620, 630, 640).

17. The power-generating system according to claim 10, characterised in that it is provided with an electronic meter being adapted to indicate the remaining time until the stored energy is wasted.

18. The power-generating system according to claim 10, wherein the container (1) houses an inverter (27) for transforming direct current into alternate current.
